(19) United States
(12) Patent Application Publication
(10) Pub. No.: US 2010/0242492 A1
(43) Pub. Date: Sep. 30, 2010

(54) DISTRIBUTED ENGINE CONTROL SYSTEMS AND GAS TURBINE ENGINES

(75) Inventors: Jef Sloat, Phoenix, AZ (US); Dwayne Michael Benson, Chandler, AZ (US); Kent Stange, Phoenix, AZ (US)

Correspondence Address: HONEYWELL/IFL;Patent Services, 101 Columbia Road, P.O.Box 2245, Morristown, NJ, 07962-2245, US

(73) Assignee: HONEYWELL INTERNATIONAL INC., Morristown, NJ (US)

(21) Appl. No.: 12/414,386

(22) Filed: Mar. 30, 2009

(51) Int. Cl. F02C 9/00; F02C 7/12; H05K 7/20

(52) U.S. Cl. 60/793; 60/39.83; 361/699

(57) ABSTRACT

Distributed engine control systems and gas turbine engines are provided. In an embodiment, a distributed engine control system includes a central controller, a plurality of nodes in operable communication with the central controller, each node including an electronic circuit and a heat transfer element adapted to absorb heat from the electronic circuit, each node in communication with the central controller, and a coolant distribution system including a plurality of coolant interfaces, a coolant line, and a coolant source, each coolant interface of the plurality of coolant interfaces adapted to contain a coolant that is adapted to absorb heat from the heat transfer element of a node of the plurality of nodes, and the coolant line adapted to provide fluid communication between the nodes of the plurality of nodes and the coolant source

### TECHNICAL FIELD

The inventive subject matter generally relates to gas turbine engines, and more particularly relates to distributed control systems for gas turbine engines.

### BACKGROUND

A gas turbine engine control system typically includes a plurality of sensors and a plurality of actuators. In most cases, sensors may be implemented at various locations in an engine and may be employed to detect engine performance parameters, such as turbine rotational velocities, engine pressures, engine temperatures, and/or other controlled parameters, such as fuel flow and inlet guide vane positions. The sensors supply feedback signals representative of the detected data to a central processing unit such as, for example, a Full Authority Digital Engine Controller (FADEC). In response to the feedback signals, the FADEC generates and supplies appropriate actuator commands to one or more of the actuators to thereby control engine operation. For example, the actuators may be used to control the position or speed of one or more components to thereby manage engine parameters affecting engine operation. In other examples, the actuators may be used to open and/or shut valves to control fuel flow or to position one or more guide vanes to influence air flow through the engine.

Although the above-described control systems operate sufficiently, they may be improved. For example, because the FADEC typically communicates with each sensor and actuator using wiring and multiple wiring harnesses, the overall weight and cost of the system may be undesirably high. Additionally, in most cases, the FADEC may control and perform numerous functions. Hence, if the FADEC is brought offline, for example, for routine maintenance, all of the FADEC function may be inoperable and aircraft downtime may be increased. Additionally, identifying a specific part of the FADEC that may need repair or replacement may take more time than desired.

Accordingly, it is desirable to have an engine control system in which the control functions are not centralized. Additionally, it is desirable to have a control system that is lighter in weight as compared to conventional FADEC systems. Additionally it is desirable to be able to identify a source of system faults with less effort than in the past. Furthermore, other desirable features and characteristics of the inventive subject matter will become apparent from the subsequent detailed description of the inventive subject matter and the appended claims, taken in conjunction with the accompanying drawings and this background of the inventive subject matter.

### BRIEF SUMMARY

Distributed engine control systems and gas turbine engines are provided.

In an embodiment, by way of example only, a distributed engine control system includes a central controller, a plurality of nodes in operable communication with the central controller, each node including an electronic circuit and a heat transfer element adapted to absorb heat from the electronic circuit, each node in operable communication with the central controller, and a coolant distribution system including a plurality of coolant interfaces, a coolant line, and a coolant source, each coolant interface of the plurality of coolant interfaces adapted to contain a coolant that is adapted to absorb heat from the heat transfer element of a node of the plurality of nodes, and the coolant line adapted to provide fluid communication between the nodes of the plurality of nodes and the coolant source.

In another embodiment, by way of example only, a gas turbine engine includes an intake section, a compressor section in flow communication with the intake section, a combustion section in flow communication with the compressor section, a turbine section in flow communication with the combustion section, an exhaust section in flow communication with the turbine section, a plurality of nodes disposed in one or more of the air intake section, the compressor section, the combustion section, the turbine section and the exhaust section, and each node including an electronic circuit and a heat transfer element adapted to absorb heat from the electronic circuit, each node in operable communication with the central controller, a central controller in operable communication with the plurality of nodes, and a coolant distribution system extending through one or more of the air intake section, the compressor section, the combustion section, the turbine section and the exhaust section, the plurality of nodes in operable communication with the central controller, the coolant distribution system including a plurality of coolant interfaces, a coolant line, and a coolant source, each coolant interface of the plurality of coolant interfaces adapted to contain a coolant that is adapted to absorb heat from the heat transfer element of a node of the plurality of nodes, and the coolant line adapted to provide fluid communication between the nodes of the plurality of nodes and the coolant source.

### BRIEF DESCRIPTION OF THE DRAWINGS

The inventive subject matter will hereinafter be described in conjunction with the following drawing figures, wherein like numerals denote like elements, and

FIG. 1 is a simplified cross-sectional view of a portion of an aircraft, according an embodiment;

FIG. 2 is a functional block diagram of a coolant distribution system including a portion of a distributed control system incorporated therein, according to an embodiment; and

FIG. 3 is a simplified, exploded view of a node, according to an embodiment.

### DETAILED DESCRIPTION

The following detailed description is merely exemplary in nature and is not intended to limit the inventive subject matter or the application and uses of the inventive subject matter. Furthermore, there is no intention to be bound by any theory presented in the preceding background or the following detailed description.

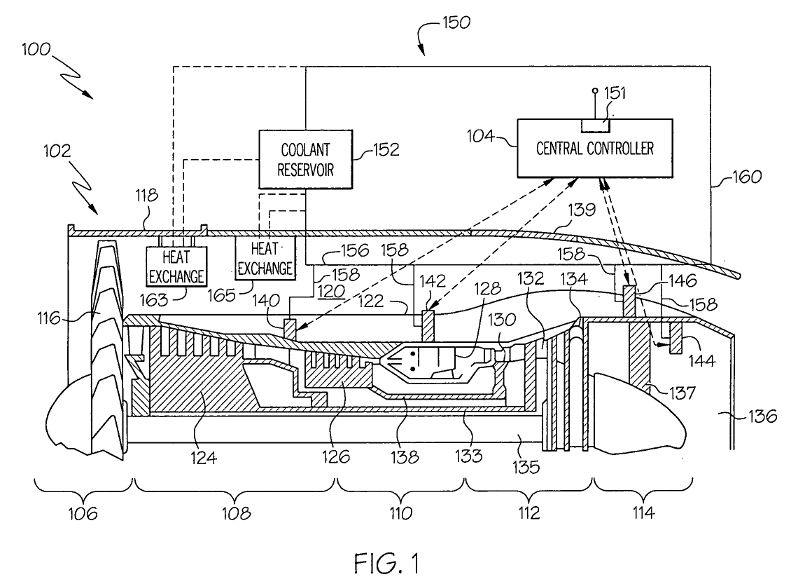

FIG. 1 is a simplified cross section view of a portion of an aircraft 100, according to an embodiment. The aircraft 100 is configured to include a distributed engine control system including various components that are located on or within an engine 102, in an embodiment. In another embodiment, the distributed engine control system may include one or more components that may be disposed at other locations throughout the aircraft 100, such as on an aircraft wing, on or around an inlet door or another section of the aircraft 100. In any case, one or more of the components of the distributed engine control system are thermally coupled to a coolant distribution system. In this way, the components can be disposed in hot sections of the engine 102 which may have temperature environments that may exceed 500° C. or, in some cases, 1400° C. during engine operation.

In an embodiment, the engine 102 is a multi-spool turbofan gas turbine engine. In other embodiments, the engine 102 may be a different type of engine, such as a turbojet engine or any other type of engine that may benefit from the inclusion of a distributed engine control system. In the depicted embodiment, the engine 102 includes an intake section 106, a compressor section 108, a combustion section 110, a turbine section 112, and an exhaust section 114. The intake section 106 includes a fan 116, which is mounted in an engine case 118. The fan 116 draws air into the intake section 106 and accelerates it. A fraction of the accelerated air exhausted from the fan 116 is directed through a bypass section 120 disposed between the engine case 118 and an engine cowl 122. The fraction of air provides a forward thrust. The remaining fraction of air exhausted from the fan 116 is directed into the compressor section 108.

The compressor section 108 includes two compressors, an intermediate pressure compressor 124, and a high pressure compressor 126. The intermediate pressure compressor 124 raises the pressure of the air directed into it from the fan 116, and directs the compressed air into the high pressure compressor 126. The high pressure compressor 126 compresses the air still further and directs the high pressure air into the combustion section 110. In the combustion section 110, which includes a combustor 128, the high pressure air is mixed with fuel and combusted. The combusted air is then directed into the turbine section 112.

In an embodiment, the turbine section 112 includes three turbines disposed in axial flow series: a high pressure turbine 130, an intermediate pressure turbine 132, and a low pressure turbine 134. The combusted air from the combustion section 110 expands through each turbine, causing each turbine to rotate. The air is then exhausted through a propulsion nozzle 136 disposed in the exhaust section 114, providing additional forward thrust. As each turbine rotates, each drives equipment in the engine 102 via concentrically disposed shafts or spools. Specifically, the high pressure turbine 130 drives the high pressure compressor 126 via a high pressure spool 138, the intermediate pressure turbine 132 drives the intermediate pressure compressor 124 via an intermediate pressure spool 133, and the low pressure turbine 134 drives the fan 116 via a low pressure spool 135.

As noted above, the distributed engine control system comprises a plurality of components that are disposed at various locations in the engine 102. In an embodiment, the distributed engine control system comprises a central controller 104 and a plurality of nodes 140, 142, 144, 146. Communication with the central controller 104 may be provided via one or more types of communication buses, such as serial buses, parallel buses, redundant buses and the like. In an example, the nodes 140, 142, 144, 146 and central controller 104 may communicate via a wireless network that operates via various radio frequency (RF) signals communication means that wirelessly carry signals between devices. Suitable wireless network protocols include, but are not limited to, a Wireless Local Area Network (WLAN) defined by IEEE 802.11in 2.4 GHz or 3.6 GHz or 5 GHz, or a Bluetooth network defined by IEEE 802.15.1, which employs frequency hopping, spread spectrum techniques centered about 2.4 GHz, a ZigBee, a wireless personal area network (WPAN) defined by IEEE 802.15.4-2006 at 868 MHz or 915 MHz or 2.4 GHz or a Wireless USB (Universal Serial Bus) in the 3.1 GHz to 10.6 GHZ range. According to an embodiment, all of the nodes 140, 142, 144, 146 communicate only with the central controller 104. In another embodiment, two or more of the nodes 140, 142, 144, 146 may be configured to communicate with each other.

As a result of employing the above-described communication schemes, the central controller 104 may be located in any location with respect to the engine 102. For example, the central controller 104 may be disposed proximate to the engine 102, such as on or adjacent to the engine case 118, in some embodiments. In another embodiment, the central controller 104 may be disposed outside of the engine 102, such as adjacent to or within a cockpit of the aircraft 100 or in any of an equipment bay within a fuselage of the aircraft 100. In any case, the central controller 104 may be adapted to control the output power of the engine 102. In an example, the central controller 104 controls a fuel flow rate and/or an airflow rate through the engine 102. To do so, the central controller 104 receives signals from one or more nodes of the plurality of nodes 140, 142, 144, 146, processes the signals from the nodes 140, 142, 144, 146, and provides commands to nodes 140, 142, 144, 146 for the functioning of the engine 102. Although not illustrated, the central controller 104 may comprise one or more processors, such as any of numerous known general-purpose microprocessors or one or more application specific processors that operate in response to program instructions. In an embodiment, the processor or processors may include on-board random access memory (RAM) and/or on-board read only memory (ROM), and program instructions that control the processor may be stored in either or both the RAM and the ROM. For example, operational software may be stored in the ROM, whereas various operating mode software routines and various operational parameters may be stored in the RAM. In other embodiments, alternative means of storing operating system software and software routines that employ various other storage schemes may be implemented. The processor or processors may be implemented using various other circuits, not just a programmable processor. For example, digital logic circuits and analog signal processing circuits could also be used. In addition, the central controller 104 may include a wireless communications means 151, such as a transceiver and an antenna.

According to an embodiment, the nodes may be disposed throughout one or more sections of the aircraft 100 and/or the engine 102. Accordingly, each node 140, 142, 144, 146 also may include a communication means. In an embodiment, the communications means may include a wire. In another embodiment, the communications means may include a transceiver and antenna. In alternate embodiments, one or more nodes may include a transmitter or a receiver, rather than a transceiver. The nodes 140, 142, 144, 146 may be used to communicate data to the central controller 104 via RF signals, in an example embodiment. The nodes 140, 142, 144, 146 may sense various physical parameters associated with the engine 102 and its operation and may communicate data describing these physical parameters to the central controller 104 via the RF signals, in an embodiment. For example, the nodes may be configured to sense position, such as a position in which a valve is disposed. In an embodiment, a node 140 may be disposed adjacent to or within a duct, such as within the bypass section 120, and may be in flow communication with a pneumatic system. In another embodiment, a node 142 may be configured to sense temperature and may be disposed adjacent to a hot section of the engine 102, such as adjacent to the combustion section 110. In such case, the node 142 may be coupled to the combustor 128, in an embodiment. In another embodiment, a node 144 may be disposed adjacent to the exhaust section 114.

In accordance with another embodiment, the nodes are configured to 140, 142, 144, 146 respond to commands provided by the central controller 104 via RF signals or signal wires. For example, one or more of the nodes 140, 142, 144, 146 may be adapted to actuate a device and the RF transmitted or wire transmitted signals from the central controller 104 may indicate parameters regarding such actuation. According to an embodiment, the device may be a valve, and hence, a node 146 may be disposed adjacent to or may be coupled to the valve. In some embodiments, valves may be adapted to control an amount of fluid flowing along a flowpath. In an example, the fluid may be air, fuel or another type of gas, and the flowpath may be defined as part of a pneumatic system, a fuel system, a hydraulic system or another system in the aircraft 100 or engine 102. Valves that may be employed for controlling fluid flow along a flowpath include, but are not limited to butterfly valves, piston-type valves, ball-type valves or another type of valve. In any case, the valves are moved through various positions to provide a desired amount of matter through the system, and the node 140, 142, 144, 146, which is coupled to the valve, is adapted to move the valve to a desired position, based on commands received from the central controller 104 via the wired or wirelessly transmitted signals. In this regard, the nodes 140, 142, 144, 146 may be disposed at any location which is adjacent to or in proximity of the valve. Examples include but are not limited to low pressure turbine control valves, high pressure turbine control valves, and transient bleed valves.

As noted above, no matter the particular location of the node 140, 142, 144, 146, at least some of the nodes 140, 142, 144, 146 may be thermally coupled to a component of the coolant distribution system, which provides coolant to the nodes 140, 142, 144, 146. Hence, the coolant distribution system is adapted to extend through various sections of the aircraft 100. In an embodiment, the coolant may comprise a liquid. For example, the liquid may comprise an ethylene glycol and water mixture coolant. In another embodiment, the liquid may comprise jet fuel. In another example, the coolant may comprise a gas, such as cooled air. The cooled air may originate from the bypass section 120, ambient air, or another cool air source.

In any case, the coolant distribution system includes a coolant line 150 and a coolant reservoir 152. The coolant line 150 is configured to provide fluid communication between the one or more nodes 140, 142, 144, 146 and the reservoir 152. According to an embodiment, the coolant line 150 includes a main distribution line 156 and one or more auxiliary lines 158. The main distribution line 156 distributes coolant from the reservoir 152 to the plurality of auxiliary lines 158, and each auxiliary line 158 leads to a corresponding node 140, 142, 144, 146. In some cases, the auxiliary lines 158 are also configured to feed into a return line 160 that directs the coolant back to the reservoir 152. In accordance with an embodiment, the lines 150, 156, 158, 160 may include pipes, which may be made of materials such as aluminum, or copper. However, the particular materials from which the lines 150, 156, 158, 160 comprise may depend on the type of coolant used. For example, in an embodiment in which fuel is employed as the coolant, the lines 150, 156, 158, 160 may comprise steel. To cool the coolant before it returns to the coolant reservoir 152, a heat exchanger 163 may be included along the return line 160, as indicated by the dashed lines. For example, the heat exchanger 163 may be disposed in the bypass section 120 of the engine and the air flowing through the bypass section 120 may be exploited to cool heated coolant flowing through the heat exchanger 163.

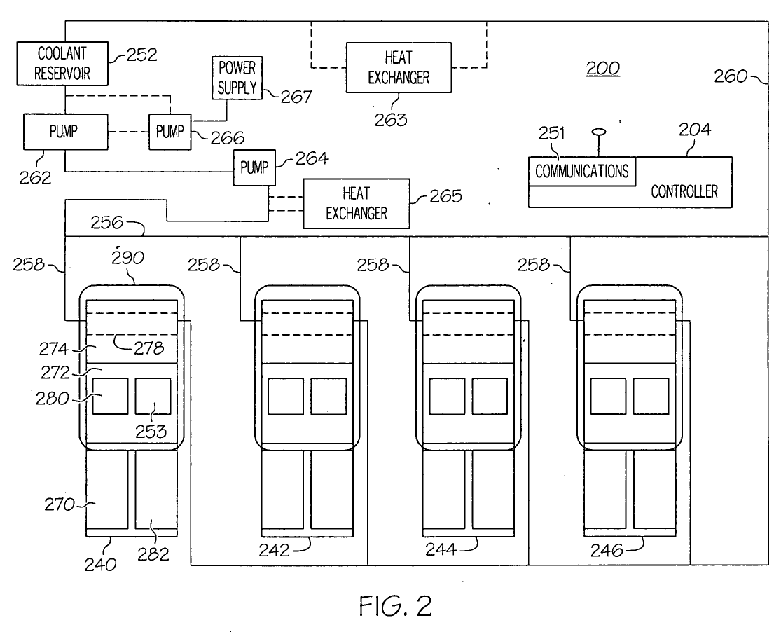

FIG. 2 is a functional block diagram of a coolant distribution system 200 including a portion of a distributed control system incorporated therein, according an embodiment. In an embodiment, the coolant distribution system 200 includes a coolant reservoir 252 that is in fluid communication with the nodes 240, 242, 244, 246 via a main distribution line 256. The main distribution line 256 delivers coolant to a plurality of auxiliary distribution lines 258, each corresponding to a node 240, 242, 244, 246. The coolant is driven through the system 200 by one or more pumps 262, 264, 266. To cool the coolant after it leaves the pumps 262, 264, 266, a heat exchanger 265 (or heat exchanger 165 in FIG. 1) may be included along the distribution line 256, as indicated by the dashed lines. After leaving a node 240, 242, 244, 246 the coolant may either circulated through an auxiliary component, such as a heat exchanger 263, or returned to the coolant reservoir 252 via a return line 260.

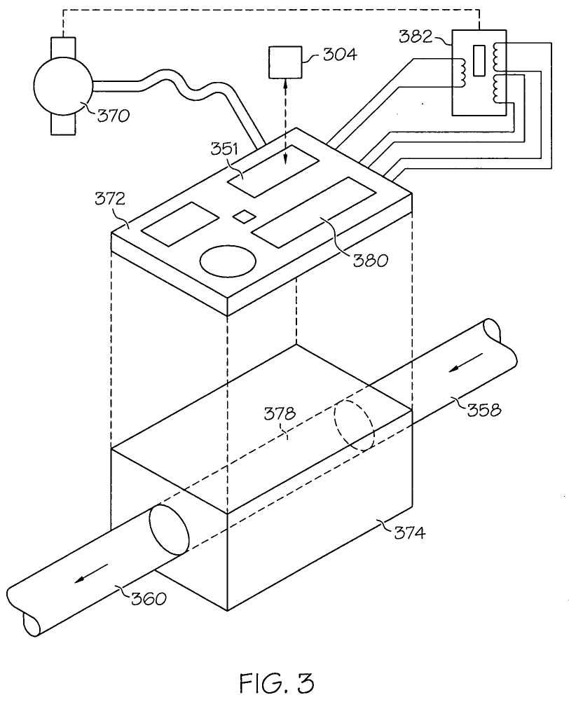

One or more of the nodes 240, 242, 244, 246 includes various components that may be selectively cooled by the coolant. FIG. 3 is a simplified, exploded view of a node 300, according to an embodiment. The node 300 may be implemented as one or more of nodes 140, 142, 144, 146 or nodes 240, 242, 244, 246, in an embodiment. In an embodiment, the node 300 includes an active element 370, a sensing element 382, an electronic circuit 372, and a coolant interface, which may include a heat transfer element 374. The active element 370 may be a device that is configured to respond to commands received from the electronic circuit 372. According to an embodiment, the active element 370 may comprise an actuator, such as a torque motor, an AC motor, a brushed or brushless DC motor, or a stepper motor) or the like. In another embodiment, the active element 370 may comprise an actuator, such as a solenoid or a guide vane. According to an embodiment, the sensing element 382 may comprise a sensor, such as a temperature sensor (e.g. resistive temperature detectors, thermistors, or thermocouples), a position sensor (e.g. a rotary variable differential transformer, a liner variable differential transformer, a potentiometer or an absolute rotary or linear position sensor) a pressure sensor (piezoresitive or bridge resistance), a proximity sensor, (inductive or capacitive) or a strain gauge. In still another embodiment, the node 300 may include a combination of sensors and actuators. In still other embodiments, other devices may be employed for the active element 370 and/or the sensing element 382. In still other embodiments, the node 300 may include one actuator from the list above or it may include one sensor from the lists above.

The electronic circuit 372 is adapted to receive commands that are communicated by a central controller 304 and to send the commands to the active element 370, in an embodiment. In another embodiment, the electronic circuit 372 is adapted to receive and process signals from the sensing element 382 and to transmit the signals to the central controller 304. In still another embodiment, the electronic circuit 372 is adapted to receive and process data from the sensing element 382 and/or the controller 304, and/or one or more of the other nodes (e.g., nodes 140, 142, 144, 146 or nodes 240, 242, 244, 246) and to process and transmit the data to the active element 370 and/or the controller 304, and/or one or more of the other nodes.

In accordance with an embodiment, the electronic circuit 372 includes a processor 380 and a communications element 351. The processor 380 may be any one of numerous known general-purpose microprocessors or an application specific processor that operates in response to program instructions. In an embodiment, the processor 380 may include on-board random access memory (RAM) and/or on-board read only memory (ROM), and program instructions that control the processor 380 may be stored in either or both the RAM and the ROM. For example, software for operating the active element 370 may be stored in the ROM, whereas various operating mode software routines and various operational parameters may be stored in the RAM. In other embodiments, alternative means of storing operating system software and software routines that employ various other storage schemes may be implemented. The processor 380 may be implemented using various other circuits, not just a programmable processor. For example, digital logic circuits and analog signal processing circuits could also be used. In any case, the processor 380 may comprise various circuits integrated in an electronics board. In some embodiments, the processor 380 may include materials that may not be capable of maintaining structural integrity when exposed to high temperature environments, such as temperatures greater than about 125° C. In other embodiments, the processor 380 may include high temperature materials, such as silicon carbide and/or silicon on insulator materials. A particular configuration of the electronic circuit 372 may depend on a specific implementation of the active component 370 and the sensing element 382. For example, in some embodiments, the electronic circuit 372 may include a torque motor driver, a linear variable differential transducer excitation circuit, an linear variable differential transducer signal conditioning circuit an analog to digital converter, built in test circuits, and the like.

To communicate signals to the central controller 304, the processor 380 is in operable communication with the communications element 351. In accordance with an embodiment, the communications element 351 may include a transmitter adapted to transmit RF or wired signals representing data processed by the processor 380. In another embodiment, the communications element 351 may include a receiver that is adapted to receive RF signals from the central controller 304. In still another embodiment, the communications element 351 may include a transceiver that is adapted to receive RF signals from the central controller 304 and to transmit RF signals received to the central controller 304.

The electronic circuit 372 may be thermally coupled to, but electrically isolated from the heat transfer element 374. In an embodiment, the heat transfer element 374 may be made of metal such as aluminum or copper and be capable of absorbing heat from the electronic circuit 372. According to an embodiment, the heat transfer element 374 is directly coupled to the electronics board of the processor 380 in a manner that promotes thermal conduction of heat energy from the electronic circuit 372. For example the heat transfer element may be bolted to copper areas on the circuit card. In another embodiment, the heat transfer element 374 may be connected to the electronic circuit 372 with mica insulators or the like. In an embodiment, the heat transfer element 374 may include mica, which may provide electrical isolation and thermal conduction to the electronic circuit 372.

According to an embodiment, the coolant interface may be defined between the heat transfer element 374 and a flow passage 378. According to an embodiment, the coolant interface may be adapted to contain the coolant that is adapted to absorb heat from the heat transfer element 374. In an embodiment, the flow passage 378 may extend through the heat transfer element 374 to allow the coolant to be in flow communication with the coolant supply line 358 and the coolant return line 360 and to receive coolant from the coolant reservoir 252 (FIG. 2). In accordance with an embodiment, the flow passage 378 may have a cross-sectional flow area in a range of from about 0.3 cm² to about 10 cm². In other embodiments, the cross-sectional flow area may be greater or less than the aforementioned range.

Returning to FIG. 2, according to an embodiment an enclosure 290 may be included as part of the nodes 240, 242, 244, 246. In an embodiment, the enclosure 290 contains an electronic circuit 272 and a heat transfer element 274 of the node 240 and is spaced apart from the electronic circuit 272 (which may be configured in a similar manner as electronic circuit 372 (FIG. 3) by including a processor 280) and the heat transfer element 274 (which may be configured in a manner similar to that of heat transfer element 274) to provide a thermally isolating air space. In an embodiment, the enclosure 290 may be mounted to the heat transfer element 274 to provide mechanical support to the enclosure 290. In other embodiments, the enclosure 290 may be mounted to the electronic circuit card 272 to provide mechanical support to the enclosure 290. In still another embodiment the enclosure 290 may be mounted to the coolant supply line 258 and the coolant return line 260 to provide mechanical support to the enclosure 290. In some embodiments, the enclosure 290 may not surround other node components, such as an active element 270 and/or a sensing element 282, both of which may be configured in a manner similar to that of active element 370 (FIG. 3) and/or the sensing element 382 (FIG. 3).

As mentioned previously, the coolant is moved through the coolant distribution system via the one or more pumps 262, 264, 266. According to an embodiment, each of the pumps 262, 264, 266 may be positioned in fluid communication in the coolant line 256 and are adapted to create a suction on the coolant reservoir 252 to circulate the coolant through the system 200. In the depicted embodiment, the first pump 262 may include a boost pump, such as a relatively low horsepower centrifugal pump, while the second pump 264 may include a high pressure pump, such as a variable displacement piston pump. In such case, the first pump 262 may provide a vacuum suction directly on the coolant reservoir 252 to provide a sufficient suction head for the second pump 264. The second pump 264 may then supply the coolant at a relatively high pressure to the remainder of the coolant line 256.

In another embodiment, a third pump 266 may be included between the coolant reservoir 252 and the first pump 262. The third pump 266 may comprise a low pressure pump that is adapted to supply fuel to the boost pump 262. For example, the third pump 266 may be configured to operate independently from the engine and may be coupled to a separate power supply 267. The power supply 267 may be an auxiliary power unit, battery, an off aircraft source of power or another type of power source. By including the separate power supply 267, the third pump 266 may continue to circulate the coolant through the coolant distribution system, even when the engine 102 is shut off.

Before or shortly after the engine is powered on, one or more of the pumps 262, 264, 266 may be energized to initiate coolant flow through the coolant distribution system 200. The coolant may flow from the coolant reservoir 252 along the main distribution line 256 and auxiliary distribution lies 258 and into each flow passage 278 of a coolant interface of the corresponding node 240, 242, 244, 246. As the coolant flows through the flow passage 278, the coolant absorbs heat that may have been absorbed by the heat transfer element 274 from the electronic circuit 272. In some embodiments, a portion of the coolant may be directed to other destinations, such as through a heat exchanger or another component capable of cooling the coolant. In other embodiments in which the coolant comprises fuel, a portion of the fuel may be directed to the combustor 128 (FIG. 1). A remainder of the coolant flows back to the coolant reservoir 252 to be recycled and re-circulated through the coolant distribution system 200.

After the engine is shut off, the engine may experience a “soak back” effect. In particular, a “soak back” effect occurs when thermal energy from various mechanically-operating components of the engine migrates to electrical components, such as the electronic circuits 272 of the nodes 240, 242, 244, 246. To alleviate the effects of “soak back”, the coolant distribution system may continue to circulate coolant through the nodes 240, 242, 244, 246 after the engine 102 is shut off. For example, a pump 266, which as mentioned above, may be coupled to a power supply 267 that is separate from the engine, may be powered on at any time to continue to circulate the coolant through the coolant distribution system 200 after engine shut off. The coolant may flow along the coolant lines 256, 258, 260, and hence, through the flow passages 278 of each node coolant interface to continue to remove heat and thereby protect the electronic circuits 272.

An engine control system has now been provided that may be located in parts of the engine with wider temperature extremes, including sections in which components may be exposed to temperatures that exceed 250° C. Because the functions of the engine control system are not centralized, repair and/or maintenance related to a single node may not affect the central controller or other nodes and thus, downtime of the engine during maintenance and/or repair may be reduced. Additionally, because the improved engine control system may be implemented with reduced wiring harnesses as compared to centralized FADEC systems, the improved system may be lighter in weight as compared to conventional FADEC systems.

While at least one exemplary embodiment has been presented in the foregoing detailed description of the inventive subject matter, it should be appreciated that a vast number of variations exist. It should also be appreciated that the exemplary embodiment or exemplary embodiments are only examples, and are not intended to limit the scope, applicability, or configuration of the inventive subject matter in any way. Rather, the foregoing detailed description will provide those skilled in the art with a convenient road map for implementing an exemplary embodiment of the inventive subject matter. It being understood that various changes may be made in the function and arrangement of elements described in an exemplary embodiment without departing from the scope of the inventive subject matter as set forth in the appended claims.

What is claimed is:

1. A distributed engine control system, comprising:
a central controller;
a plurality of nodes in operable communication with the central controller, each node including an electronic circuit and a heat transfer element adapted to absorb heat from the electronic circuit, each node in communication with the central controller; and
a coolant distribution system including a plurality of coolant interfaces, a coolant line, and a coolant source, each coolant interface of the plurality of coolant interfaces adapted to contain a coolant that is adapted to absorb heat from the heat transfer element of a node of the plurality of nodes, and the coolant line adapted to provide fluid communication between the nodes of the plurality of nodes and the coolant source.

2. The distributed engine control system of claim 1, wherein the coolant distribution system further comprises a pump in fluid communication with the coolant line, the pump adapted to circulate the coolant through the coolant distribution system.

3. The distributed engine control system of claim 1, wherein the coolant distribution system is adapted to circulate fuel as the coolant.

4. The distributed engine control system of claim 1, wherein the coolant distribution system is adapted to circulate a non-fuel fluid as the coolant.

5. The distributed engine control system of claim 1, wherein the plurality of nodes includes a first node comprising a sensor.

6. The distributed engine control system of claim 1, wherein the plurality of nodes includes a first node comprising an actuator.

7. The distributed engine control system of claim 1, wherein the heat transfer element comprises a heat sink.

8. The distributed engine control system of claim 1, wherein the central controller and the plurality of nodes communicate wirelessly.

9. The distributed engine control system of claim 1, further comprising signal wires coupling the central controller and the plurality of nodes.

10. A gas turbine engine comprising:
an intake section;
a compressor section in flow communication with the intake section;
a combustion section in flow communication with the compressor section;
a turbine section in flow communication with the combustion section;
an exhaust section in flow communication with the turbine section;
a plurality of nodes disposed in or adjacent to one or more of the air intake section, the compressor section, the combustion section, the turbine section and the exhaust section, and each node including an electronic circuit and a heat transfer element adapted to absorb heat from the electronic circuit, each node in operable communication with the central controller;
a central controller in operable communication with the plurality of nodes; and
a coolant distribution system extending through one or more of the air intake section, the compressor section, the combustion section, the turbine section and the exhaust section, the plurality of nodes in operable communication with the central controller, the coolant distribution system including a plurality of coolant interfaces, a coolant line, and a coolant source, each coolant interface of the plurality of coolant interfaces adapted to contain a coolant that is adapted to absorb heat from the heat transfer element of a node of the plurality of nodes, and the coolant line adapted to provide fluid communication between the nodes of the plurality of nodes and the coolant source.

11. The gas turbine engine of claim 10, wherein the coolant distribution system further comprises a pump in fluid communication with the coolant line, the pump adapted to circulate the coolant through the coolant distribution system.

12. The gas turbine engine of claim 10, wherein the intake section includes a bypass air flow and the gas turbine engine further comprises a first heat exchanger disposed within the bypass air flow.

13. The gas turbine engine of claim 10, wherein the combustion section includes a combustor and a first node of the plurality of nodes is coupled to the combustor.

14. The gas turbine engine of claim 10, wherein the coolant distribution system is adapted to circulate a non-fuel fluid as the coolant.

15. The gas turbine engine of claim 10, wherein the plurality of nodes includes a first node comprising a sensor.

16. The gas turbine engine of claim 10, wherein the plurality of nodes includes a first node comprising an actuator.

17. The gas turbine engine of claim 10, wherein the heat transfer element comprises a heat sink.

18. The gas turbine engine of claim 10, further comprising signal wires coupling the central controller and the plurality of nodes.
